(19) United States
(12) Patent Application Publication
(10) Pub. No.: US 2025/0125586 A1
(43) Pub. Date: Apr. 17, 2025

(54) VERTICAL CAVITY SURFACE EMITTING LASER DEVICE WITH CURRENT-BLOCKING REFLECTOR

(71) Applicant: Lumentum Operations LLC, San Jose, CA (US)

(72) Inventors: Jun YANG, Cupertino, CA (US); Guowei ZHAO, Milpitas, CA (US); Eric R. HEGBLOM, Sunnyvale, CA (US); Yeyu ZHU, San Jose, CA (US); Yuefa LI, San Jose, CA (US); Matthew Glenn PETERS, Menlo Park, CA (US)

(21) Appl. No.: 18/536,467

(22) Filed: Dec. 12, 2023

Related U.S. Application Data
(60) Provisional application No. 63/590,865, filed on Oct. 17, 2023.

(51) Int. Cl. H01S 5/183; H01S 5/30; H01S 5/42

(52) U.S. Cl. CPC H01S 5/18361; H01S 5/18311; H01S 5/18394; H01S 5/3095; H01S 5/423

(57) ABSTRACT

An emitter includes a substrate; a current-blocking distributed Bragg reflector (DBR) arranged on the substrate, wherein the current-blocking DBR includes a plurality of p-n junctions connected vertically in series to form a bidirectional current-blocking structure; a bottom contact layer arranged on the current-blocking DBR; a bottom DBR arranged on the bottom contact layer; a top DBR arranged on the bottom DBR; an active region configured to generate a laser light, wherein the active region is arranged between the bottom DBR and the top DBR; a top contact layer arranged on the top DBR; and an optical output arranged over the top DBR, wherein the emitter is configured to emit the laser light via the optical output.

### CROSS-REFERENCE TO RELATED APPLICATION

This Patent application claims priority to U.S. Patent Application No. 63/590,865, filed on Oct. 17, 2023, and entitled “VERTICAL CAVITY SURFACE EMITTING LASER DEVICE WITH CURRENT-BLOCKING REFLECTOR.” The disclosure of the prior Application is considered part of and is incorporated by reference into this Patent Application.

### TECHNICAL FIELD

The present disclosure relates generally to an emitter device with a current-blocking reflector.

### BACKGROUND

A vertical-cavity surface-emitting laser (VCSEL) is a type of semiconductor laser diode (e.g., a laser resonator) with laser beam emission perpendicular to a top surface or a bottom surface of the device. VCSELs typically include two distributed Bragg reflector (DBR) mirrors arranged parallel to a wafer surface with an active region arranged between the two DBR mirrors. The active region includes one or more quantum wells for laser light generation. VCSELs are widely used in various applications, such as data communications, sensing, and optical interconnects, due to advantages over other types of lasers. For example, VCSELs typically have lower power consumption (e.g., VCSELs require much lower power to operate than other types of lasers, making them more energy-efficient and cost-effective), are capable of high-speed operation (e.g., making VCSELs ideal for data communications and other applications that require fast signal transmission), have narrow beam divergence (e.g., the narrow beam divergence of VCSELs allows for high coupling efficiency with optical fibers and other components, making VCSELs easier to integrate into optical systems), and have high reliability (e.g., VCSELs have a long operating lifetime and are less prone to failure than other types of lasers).

Different applications, such as three-dimensional sensing and data communications, may use semiconductor lasers emitting at different wavelength bands. For example, short-range communications may use VCSELs emitting at around 850 nanometers (nm), whereas long-range communications may use VCSELs emitting above 1.3 micrometers (μm) or even above 1.5 μm. Three-dimensional sensing applications, such as light detection and ranging (LiDAR), may use VCSELs emitting at different wavelengths such as 905 nm and 940 nm to enable varied functions.

A typical VCSEL has a sandwich structure mainly consisting of a top distributed Bragg reflector (DBR), a bottom DBR, and an active region (e.g., an active layer) arranged between the top DBR and the bottom DBR. Each DBR is made of multiple alternatively stacked high-index layers and low-index layers, and each layer has an optical thickness of odd integer of ¼-lambda (¼, ¾, . . . ), where an optical thickness of one lambda is the length of one wavelength divided by the refractive index. High-index means a relatively higher value of an optical refractive index, and low-index means a relatively lower value of an optical refractive index. Optionally, a DBR may include gradient layers that provide a smoother transition between different energy bands corresponding to high-index and low-index semiconductor materials. The top DBR, the active region, and the bottom DBR form an optical cavity with gain material.

### SUMMARY

In some implementations, an emitter includes a substrate; a current-blocking DBR arranged on the substrate, wherein the current-blocking DBR includes a plurality of p-n junctions connected vertically in series to form a bidirectional current-blocking structure; a bottom contact layer arranged on the current-blocking DBR; a bottom DBR arranged on the bottom contact layer; a top DBR arranged on the bottom DBR; an active region configured to generate a laser light, wherein the active region is arranged between the bottom DBR and the top DBR; a top contact layer arranged on the top DBR; and an optical output arranged over the top DBR, wherein the emitter is configured to emit the laser light via the optical output.

In some implementations, an emitter array includes a substrate; a first emitter arranged on the substrate, wherein the first emitter comprises: a first current-blocking DBR arranged on the substrate, wherein the first current-blocking DBR includes a first plurality of p-n junctions connected vertically in series to form a first bidirectional current-blocking structure; a first bottom contact layer arranged on the first current-blocking DBR and associated with a first current; a first bottom DBR arranged on the first bottom contact layer; a first top DBR arranged on the first bottom DBR; a first active region configured to generate a first laser light, wherein the first active region is arranged between the first bottom DBR and the first top DBR; a first top contact layer arranged on the first top DBR and associated with a first current; and a first optical output arranged over the first top DBR, wherein the first emitter is configured to emit the first laser light via the first optical output; a second emitter arranged on the substrate, wherein the second emitter is adjacent to the first emitter, and wherein the second emitter comprises: a second current-blocking DBR arranged on the substrate, wherein the second current-blocking DBR includes a second plurality of p-n junctions connected vertically in series to form a second bidirectional current-blocking structure; a second bottom contact layer arranged on the second current-blocking DBR and associated with a second current; a second bottom DBR arranged on the second bottom contact layer; a second top DBR arranged on the second bottom DBR; a second active region configured to generate a second laser light, wherein the second active region is arranged between the second bottom DBR and the second top DBR; a second top contact layer arranged on the second top DBR and associated with the second current; and a second optical output arranged over the second top DBR, wherein the second emitter is configured to emit the second laser light via the second optical output; and an isolation region configured to electrically isolate the first emitter and the second emitter, wherein the isolation region is arranged laterally between the first bottom contact layer and the second bottom contact layer, and laterally between the first current-blocking DBR and the second current-blocking DBR.

In some implementations, a method of manufacturing an emitter includes forming a current-blocking DBR on a substrate, wherein the current-blocking DBR includes a plurality of p-n junctions connected vertically in series to form a bidirectional current-blocking structure; forming a bottom contact layer on the current-blocking DBR, wherein the current-blocking DBR is configured to electrically isolate the substrate from the bottom contact layer; forming a bottom DBR on the bottom contact layer; forming an active region on the bottom DBR, wherein the active region is configured to generate a laser light; forming a top DBR on the active region; forming a top contact layer on the top DBR; and forming an optical output over the top DBR, wherein the optical output is configured to emit the laser light from the emitter.

### BRIEF DESCRIPTION OF THE DRAWINGS

FIGS. 1A and 1B are diagrams depicting a top-view of an example emitter and a cross-sectional view of example emitter along the line X-X, respectively.

FIG. 2 shows a cross-sectional view of an emitter according to one or more implementations.

FIG. 3 shows examples of a p-n junctions connected vertically in opposite series to form current-blocking structures according to one or more implementations.

FIG. 4 shows a current-blocking DBR according to one or more implementations.

FIG. 5 shows a current-blocking DBR according to one or more implementations.

FIG. 6 shows a current-blocking DBR according to one or more implementations.

FIG. 7 shows a current-blocking DBR according to one or more implementations.

FIG. 8 shows a current-blocking DBR according to one or more implementations.

FIG. 9 shows an addressable emitter array according to one or more implementations.

FIG. 10 shows an addressable emitter array according to one or more implementations.

FIG. 11 is a flowchart of an example process associated with a vertical cavity surface emitting laser device.

### DETAILED DESCRIPTION

The following detailed description of example implementations refers to the accompanying drawings. The same reference numbers in different drawings may identify the same or similar elements.

In the last few years, VCSEL arrays have achieved extensive market applications on both consumer mobile devices for 3D-sensing at short range (less than a few meters) and LiDAR for longer range detecting. Furthermore, multi-junction schemes enable high peak power densities and decrease an operating current for a desired optical power. Such higher voltages and lower operating currents make LiDAR modules more efficient. In view of VCSEL arrays offering a potential for LiDAR scanning without moving parts, emitter arrays, such as an array of stripes of emitters or emitter array matrices, should be matrix-addressable. In other words, each emitter of an emitter array should be selectively activated/deactivated.

Vertical emitters, such as VCSELs, and vertical emitter arrays are typically fabricated with an epitaxial structure grown on a conductive substrate (typically an n-type substrate) which has better quality than semi-insulating (SI) type substrates. The conductive substrate makes it challenging to produce a matrix-addressable emitter array. Some emitter arrays may use an SI substrate or an electrical isolation structure, such as an NPN (or a PNP) scheme, to isolate different emitters (e.g., different VCSELs) of the emitter array. However, SI substrates typically have a higher density of defects as compared to conductive substrates (e.g., GaAs or InP substrates). Subsequent epitaxial structures grown on SI substrates may have lower quality than epitaxial structures grown on conductive substrates. Another approach may utilize an isolation layer or multiple isolation layers employed to block current cross talk between each individual emitter of an emitter array in an emitter chip. The isolation layers may include a PNP layer, an NPN layer, a PNPN layer, an NPNP layer, and/or an un-doped layer (e.g., an intrinsic layer, i-type). An epitaxy of additional isolation layers makes an overall epitaxial structure increase in epitaxy thickness. Adding isolation layers adds complexity and cost to a fabrication of the VCSELs. Moreover, high-optical-power-density LiDAR using multi-junction VCSELs may require high voltage operation so as to demand an isolation between substrate and emitter, emitter-to-emitter, or subarray-to-subarray with a high voltage range greater than 10 V. Higher operating voltages typically require thicker isolation layers to meet isolation requirements for proper operation, which again adds cost to the fabrication of the VCSELs. Higher complexity, higher cost, and thicker devices are typically undesired.

Some implementations disclosed herein provide a current-blocking DBR to provide electrical isolation. The current-blocking DBR may be incorporated in, for example, a bottom DBR of an emitter (e.g., of a VCSEL) or may be provided as an additional DBR that is adjacent to a substrate (e.g., a conductive substrate, such as an n-type substrate) on which the current-blocking DBR is formed.

The current-blocking DBR may include alternating p-doped and n-doped layers that form a series of p-n-p-n junctions or p-i-n-i-p-i-n junctions to block or isolate current. For example, a portion of a layer stack of the high-index layers and low-index layers may be p-doped or n-doped alternatively or periodically. For example, the high-index layers may be p-type, and the low-index layers may be n-type, or vice versa. In some implementations, the current-blocking DBR may include an intrinsic layer (i-layer) between p-doped and n-doped layers. Thus, the portion of the layer stack may be configured for current-blocking while also performing optical reflection for light within the optical cavity. In other words, the current-blocking DBR has current-blocking layers that also perform as optical reflector layers. An active region may be a single junction that includes quantum wells or may include multi-junctions that include tunnel-junction connected multiple junctions, where each junction may have quantum wells. Thus, DBR reflection may be combined with current-blocking so as to simplify an epitaxial structure of an emitter. In addition, an electrical isolation using a certain number of current-blocking DBR pairs may be enhanced without adding extra thickness compared to conventional PNP or NPN isolation.

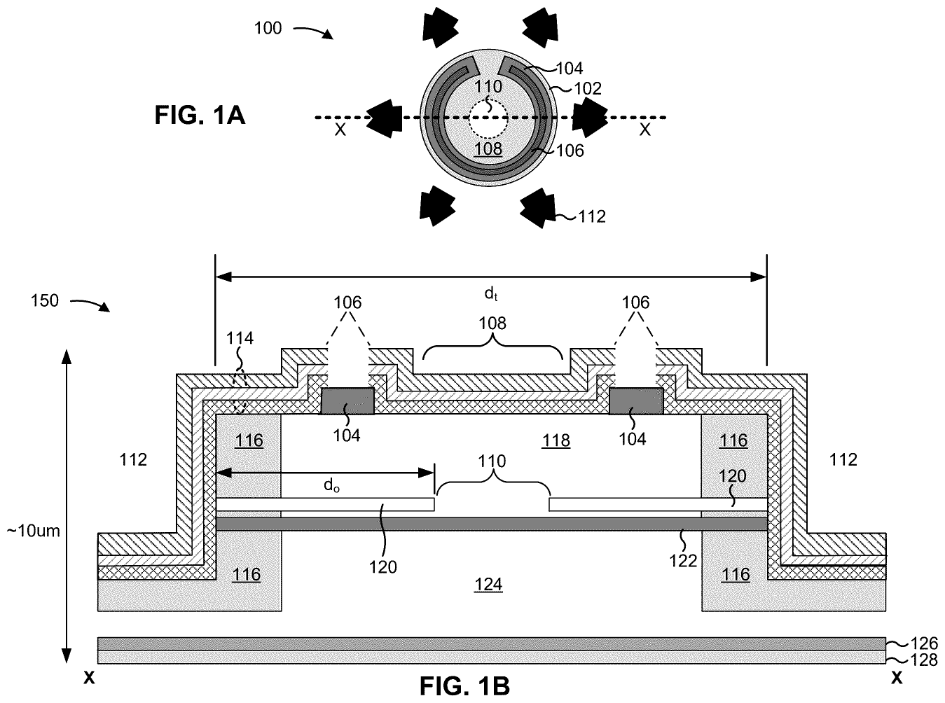

FIGS. 1A and 1B are diagrams depicting a top-view of an example emitter 100 and a cross-sectional view 150 of example emitter 100 along the line X-X, respectively. As shown in FIG. 1A, emitter 100 may include a set of emitter layers constructed in an emitter architecture. In some implementations, emitter 100 may correspond to one or more vertical-emitting devices described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown by the medium gray and dark gray areas in FIG. 1A, emitter 100 includes an ohmic metal layer 104 (e.g., a P-Ohmic metal layer or an N-Ohmic metal layer) that is constructed in a partial ring-shape (e.g., with an inner radius and an outer radius). The medium gray area shows an area of ohmic metal layer 104 covered by a protective layer (e.g. a dielectric layer or a passivation layer) of emitter 100 and the dark gray area shows an area of ohmic metal layer 104 exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Not shown in FIG. 1A, emitter 100 includes a protective layer in which via 106 is formed (e.g., etched). The dark gray area shows an area of ohmic metal layer 104 that is exposed by via 106 (e.g., the shape of the dark gray area may be a result of the shape of via 106) while the medium grey area shows an area of ohmic metal layer 104 that is covered by some protective layer. The protective layer may cover all of the emitter other than the vias. As shown, via 106 is formed in a partial ring-shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring-shape or a split ring-shape.

As further shown, emitter 100 includes an optical aperture 108 in a portion of emitter 100 within the inner radius of the partial ring-shape of ohmic metal layer 104. Emitter 100 emits a laser beam via optical aperture 108. As further shown, emitter 100 also includes a current confinement aperture 110 (e.g., an oxide aperture formed by an oxidation layer of emitter 100 (not shown)). Current confinement aperture 110 is formed below optical aperture 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112, in practice, other configurations are possible, such as a compact emitter that includes five trenches 112, seven trenches 112, or another quantity of trenches. In some implementations, trench 112 may encircle emitter 100 to form a mesa structure dt. As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations are possible. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a protective layer 114 (e.g. a dielectric passivation/mirror layer), and an ohmic metal layer 104. As shown, emitter 100 may have, for example, a total height that is approximately 10 μm.

Backside cathode layer 128 may include a layer that makes electrical contact with substrate layer 126. For example, backside cathode layer 128 may include an annealed metallization layer, such as an AuGeNi layer, a PdGeAu layer, or the like.

Substrate layer 126 may include a base substrate layer upon which epitaxial layers are grown. For example, substrate layer 126 may include a semiconductor layer, such as a GaAs layer, an InP layer, and/or another type of semiconductor layer.

Bottom mirror 124 may include a bottom reflector layer of emitter 100. For example, bottom mirror 124 may include a DBR. Part of the bottom mirror 124 may include a current-blocking DBR that includes alternating p-doped and n-doped layers. In some implementations, the current-blocking DBR may include an intrinsic layer (i-layer) between p-doped and n-doped layers.

Active region 122 may include a layer that confines electrons and defines an emission wavelength of emitter 100. For example, active region 122 may be a quantum well.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an Al₂O₃ layer formed as a result of oxidation of an AlAs or AlGaAs layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 4 μm to approximately 20 μm. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as do in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer and which may act as an additional DBR. For example, protective layer 114 may include one or more sub-layers (e.g., a dielectric passivation layer and/or a mirror layer, a SiO₂ layer, a Si₃N₄ layer, an Al₂O₃ layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bond pad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor and/or may provide a non-rectifying electrical junction and/or may provide a low-resistance contact. In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B is provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100 and any layer may comprise more than one layer.

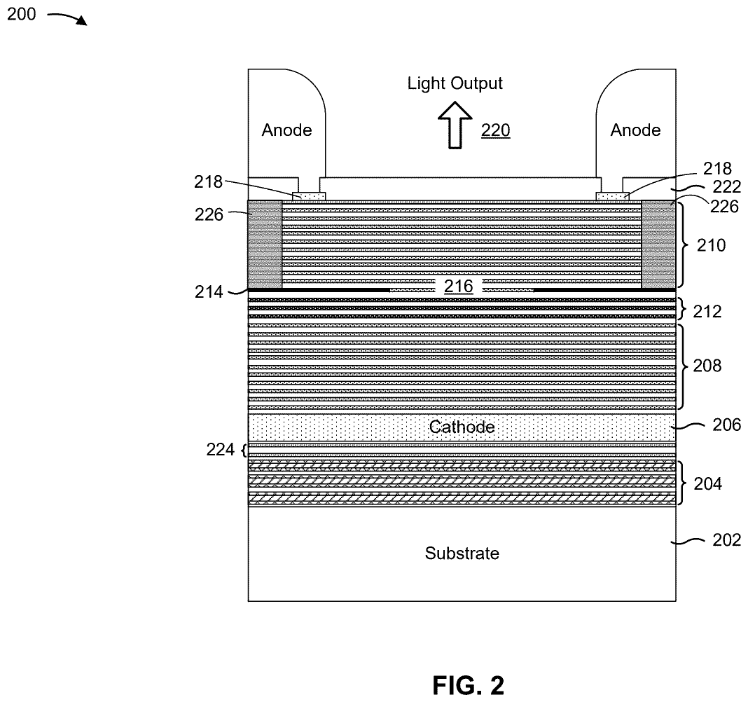

FIG. 2 shows a cross-sectional view of an emitter 200 according to one or more implementations. The emitter 200 may be a VCSEL device (e.g., a VCSEL emitter) that includes a substrate 202, a current-blocking DBR 204 arranged on the substrate 202, a bottom contact layer 206 arranged on the current-blocking DBR 204, a bottom DBR 208 arranged on the bottom contact layer 206, a top DBR 210 arranged on the bottom DBR 208, an active region 212 arranged between the bottom DBR 208 and the top DBR 210, an oxidation layer 214 that defines a current confinement aperture 216 and provides optical and electrical confinement of the emitter 200, a top contact layer 218 arranged on the top DBR 210, and an optical output 220 arranged over the top DBR 210 for light output. The active region 212 may generate a laser light, and the emitter 200 may be configured to emit the laser light via the optical output 220. In some implementations, the active region 212 may be a quantum well active region.

Additionally, the emitter 200 may include a protective layer 222 arranged on the top DBR 210. For example, the protective layer 222 may be a passivation layer.

In some implementations, the emitter 200 may include a spacer DBR 224 arranged between the current-blocking DBR 204 and the bottom contact layer 206 (e.g., above the current-blocking DBR 204 and under the bottom contact layer 206). The spacer DBR 224 may include doped or undoped layers. In some implementations, the spacer DBR 224 may be part of the current-blocking DBR 204.

In some implementations, the emitter 200 may include implant isolation region 226 for electrical isolation. The implant isolation region 226 may include an implant isolation material. In some implementations, the implant isolation region 226 may be implanted into an edge region of the top DBR 210.

The top contact layer 218 may include metal contacts or contact pads configured to make contact with a metal layer, such as an ohmic metal layer. In some implementations, the bottom contact layer 206 may be a contact buffer for a cathode electrical connection, and the top contact layer 218 may be an anode contact layer for an anode electrical connection. Alternatively, the bottom contact layer 206 may be an anode buffer for the anode electrical connection, and the top contact layer 218 may be a cathode contact layer for the cathode electrical connection. The bottom contact layer 206 and the top contact layer 218 may be configured to cause an electric current to flow between the bottom contact layer 206 and the top contact layer 218 for producing the laser light at the active region 212. For example, a voltage may be applied across the bottom contact layer 206 and the top contact layer 218 to activate the emitter 200 and to generate the electric current.

The substrate may be a GaAs, InP, InGaAs, GaSb, Si, Ge, GaP, GaN, ZnO, or a sapphire substrate, which is utilized to grow an epitaxial structure on top. The substrate may be an n-type, a p-type, a semi-insulating type, an insulating type, or a conductive type. The current-blocking DBR 204 may be formed directly on (e.g., in direct contact with) the substrate 202. The current-blocking DBR 204 includes a plurality of p-n junctions connected vertically in series to form a bidirectional current-blocking structure. For example, the plurality of p-n junctions may be equivalent to a series of current-blocking diodes that are arranged opposite to each other in series. The current-blocking DBR 204 may electrically isolate the substrate 202 from the bottom contact layer 206 (e.g., by providing current isolation between the bottom contact layer 206 and the substrate 202). For example, the current-blocking DBR 204 may prevent leakage current from flowing from the bottom contact layer 206 to the substrate 202, or vice versa. Thus, the current-blocking DBR 204 may be used to electrically isolate the emitter 200 from other emitters and/or other current sources to ensure the active region 212 produces laser light only when intended. In addition, the current-blocking DBR 204 is an optical reflector configured to reflect a portion of the laser light generated by the active region 212 toward the optical output 220. Thus, the current-blocking DBR 204 provides dual functionality by providing both electrical isolation and optical reflection.

The current-blocking DBR 204 may include a plurality of alternately stacked high-index layers and low-index layers, with the high-index layers being p-doped and the low-index layers being n-doped, or the high-index layers being n-doped and the low-index layers being p-doped. Thus, alternating p-doped and n-doped layers may be formed within the current-blocking DBR 204 to form the plurality of p-n junctions.

In some implementations, a first part of each high-index layer is p-doped and a second part of each high-index layer is n-doped such that the plurality of p-n junctions are formed with the low-index layers. Additionally, or alternatively, a first part of each low-index layer is p-doped and a second part of each low-index layer is n-doped such that the plurality of p-n junctions are formed with the high-index layers.

In some implementations, the plurality of p-n junctions may include a plurality of p-i-n junctions. For example, an intrinsic layer (e.g., undoped layer or i-layer) may be provided between p-doped and n-doped layers that form the p-n junctions. Each intrinsic layer may be thin enough and/or doping concentrations of the p-doped and n-doped layers may be high enough that p-n junctions are formed (e.g., a depletion region is formed between the p-doped and n-doped layers). Thus, the current-blocking DBR 204 may include a plurality of intrinsic layers, with each intrinsic layer being arranged between a respective pair of p-doped and n-doped layers of the current-blocking DBR 204. In some implementations, each intrinsic layer of the plurality of intrinsic layers is part of a respective high-index layer of the current-blocking DBR 204, or is part of a respective low-index layer of the current-blocking DBR 204. In other words, a first part of each high-index layer may be doped and a second part of each high-index layer may be undoped (intrinsic), and/or a first part of each low-index layer may be doped and a second part of each low-index layer may be undoped (intrinsic). Thus, each high-index layer may have doped sublayer and an undoped, intrinsic sublayer, and/or each low-index layer may have doped sublayer and an undoped, intrinsic sublayer.

In some implementations, the current-blocking DBR 204 may include a plurality of gradient layers. Each gradient layer may be arranged between a respective pair of high-index and low-index layers of the current-blocking DBR 204. Additionally, each gradient layer may have a respective intermediate refractive index value between a high refractive index value and a low refractive index value of the respective pair of high-index and low-index layers.

In some implementations, the plurality of gradient layers may provide a gradual semiconductor band-gap change or a stepped semiconductor band-gap change between high-index and low-index materials of the alternately stacked high-index layers and low-index layers.

In some implementations, the current-blocking DBR 204 may include a plurality of alternately stacked high-index layers and low-index layers. Each low-index layer may include a first plurality of gradient sublayers that provide a first transition in refractive index across a range of low refractive indices. In addition, each high-index layer may include a second plurality of gradient sublayers that provide a second transition in refractive index across a range of high refractive indices. Thus, the refractive indices of the current-blocking DBR 204 may have a periodicity that changes, vertically, from a minimum index value to a maximum index value. The high-index layers may be p-doped and the low-index layers may be n-doped, or the high-index layers may be n-doped and the low-index layers may be p-doped.

In some implementations, the current-blocking DBR 204 may a plurality of alternately stacked high-index layers and low-index layers that form a plurality of DBR pairs. Each DBR pair may include a respective neighboring pair of high-index and low-index layers. In addition, plurality of DBR pairs may be alternately p-doped and n-doped to form the plurality of p-n junctions. For example, both high-index and low-index layers of a first DBR pair may be p-doped, and both high-index and low-index layers of a second DBR pair may be n-doped. The first DBR pair and the second DBR pair may be arranged to form one of the p-n junctions of the current-blocking DBR 204. For example, the first DBR pair and the second DBR pair may be adjacent DBR pairs. In some implementations, each DBR pair may include an intrinsic layer arranged between the respective neighboring pair of high-index and low-index layers. Thus, each DBR may include a high-index layer, an intrinsic layer, and a low-index layer. In some implementations, each DBR pair may include one or more gradient layers arranged between the respective neighboring pair of high-index and low-index layers. Thus, each DBR pair may include a high-index layer, one or more gradient layers, and a low-index layer. In some implementations, each DBR pair may be separated by an intrinsic layer.

In some implementations, the current-blocking DBR 204 and the bottom DBR 208 may be different sections of a same DBR. In some implementations, the current-blocking DBR 204 and the bottom DBR 208 may be different DBRs. However, for simplicity, the current-blocking DBR 204 may be regarded as a first DBR, the bottom DBR 208 may be regarded as a second DBR, and the top DBR 210 may be regarded as a third DBR. Thus, the emitter 200 may include at least three DBRs, with the DBR arranged in contact with or most proximate to the substrate 202 being the current-blocking DBR 204. In some implementations, the spacer DBR 224 may be a fourth DBR, or may be part of the current-blocking DBR 204 and/or the bottom DBR 208.

To form a PNPN junction (e.g., a PNPN diode) or an NPNP junction (e.g., a NPNP diode) in a DBR, the high-index layers of the DBR may be p-doped, while low-index layers of the DBR may be n-doped. Alternatively, the high-index layers of the DBR may be n-doped, while the low-index layers of the DBR may be p-doped. The n-type doping may use silicon (Si), sulfur(S), selenium (Se), and/or tellurium (Te) as a dopant. The p-type doping may use carbon (C), zinc (Zn), beryllium (Be), and/or magnesium (Mg) as a dopant.

The current-blocking DBR 204 may be configured to perform optical reflection for light within an optical cavity of the emitter 200. In other words, the current-blocking DBR 204 may have current-blocking structures that are formed by (oppositely doped) optical reflector layers. The top DBR 210, the active region 212, and the bottom DBR 208, and the current-blocking DBR 204 may form the optical cavity with gain material.

From an optical reflection perspective, the current-blocking DBR 204 utilized for blocking current may be a DBR, a DBR-like optical reflector, or an optical reflector that includes multiple layers and provides a certain amount of optical reflection. Also, the current-blocking layers may be a group of DBR layers, or only part of the current-blocking layers may be a group of DBR layers. The current-blocking reflector may include additional spacer layers, interlayers, gradient layers, buffer layers, and/or cavity layers.

In addition, one or more aspects may be included in the above-described implementations, including (1) multi-junction VCSELs described in the context herein can have one, two, three, or more junctions; (2) an electric polarity of the VCSEL from the top to bottom can be either a p-i-n or n-i-p structure. A top semiconductor contact or cap can be either a p-type semiconductor or an n-type semiconductor. Also, all or part of a p-DBR can be replaced by an n-DBR by using a tunnel junction, or vice versa; (3) oxide-confined VCSELs may have one, two, or more oxide layers at either a p-side or an n-side; (4) the use of an optical aperture layer in VCSELs as current and mode confinement is optional and can be replaced with different approaches such as implantation passivation, mesa or moat trench isolation, or a buried tunnel junction; (5) the substrate may be a GaAs, InP, InGaAs, GaSb, Si, Ge, GaP, GaN, ZnO, or a sapphire substrate, which is utilized to grow an epitaxial structure on top. The substrate may be an n-type, a p-type, a semi-insulating type, an insulating type, or a conductive type. Even if epitaxy is used on a semi-insulating or an insulating substrate, the implementations described herein may improve electrical isolation, for example, in a case where a vertical isolation region does not extend entirely down to the substrate.

As indicated above, FIG. 2 is provided as an example. Other examples may differ from what is described with regard to FIG. 2.

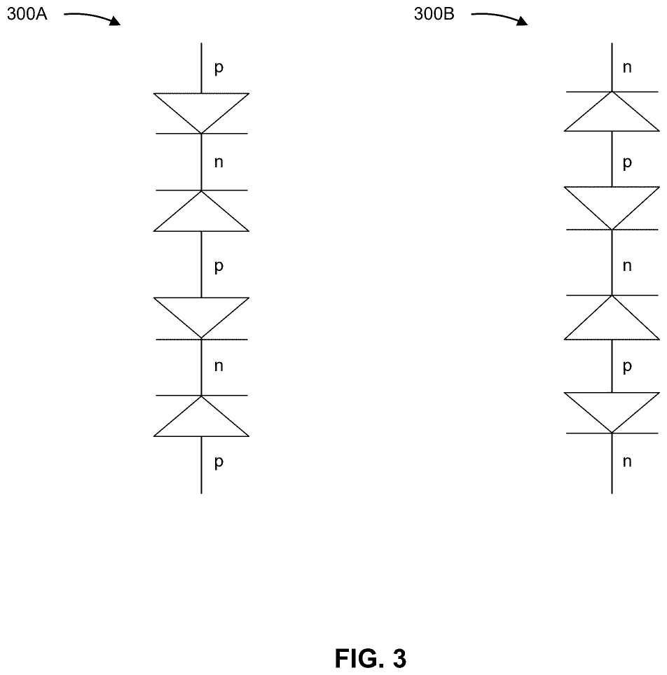

FIG. 3 shows an example 300A of a schematic diagram of a p-n-p-n diode in opposite series, which may be formed by a current-blocking DBR with alternating p-type high-index layers and n-type low-index layers. Additionally, FIG. 3 shows an example 300B of a schematic diagram of an n-p-n-p diode in opposite series, which may be formed by a current-blocking DBR with alternating n-type high-index layers and p-type low-index layers.

FIG. 3 is provided as an example. Other examples may differ from what is described with regard to FIG. 3.

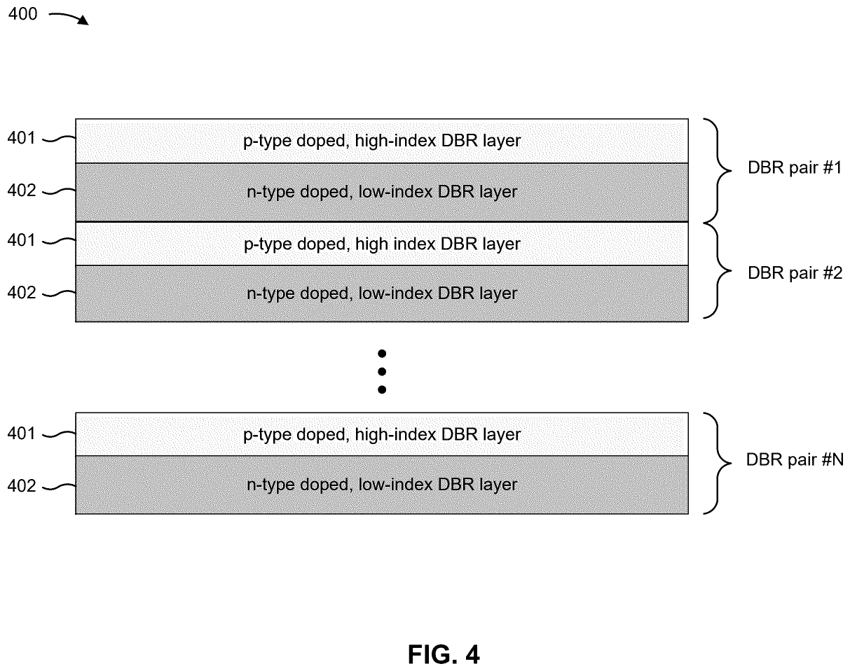

FIG. 4 shows a current-blocking DBR 400 according to one or more implementations. The current-blocking DBR 400 may be implemented as the current-blocking DBR 204 of emitter 200. The current-blocking DBR 400 includes alternating p-type high-index layers 401 and n-type low-index layers 402.

In addition, the current-blocking DBR 400 may include one or more gradient layers (not illustrated) between neighboring pairs of high-index and low-index layers. For example, one or more gradient layers may be provided between each neighboring pair of high-index and low-index layers of the current-blocking DBR 400. The one or more gradient layers may be either n-doped or p-doped, or n-doped in one part and p-doped in a remaining part.

A neighboring pair of high-index and low-index layers (i.e., a DBR pair) may include two oppositely doped layers, where a full section of the high-index layer 401 is p-type doped, and a full section of the low-index layer 402 is n-type doped. There may be other different configurations or schemes. For example, part of the high-index layer 401 and/or an adjacent part of the low-index layer 402 may be p-doped, and a remaining part of the high-index layer 401 and/or an adjacent part of the low-index layer 402 may be n-doped. Thus, each high-index layer 401 may be formed by two or more high-index sublayers, which may have a same doping type or opposite doping types. The two or more high-index sublayers may have a same refractive index or different refractive indices to form a refractive index gradient. Additionally, each low-index layer 402 may be formed by two or more low-index sublayers, which may have a same type doping or opposite dopings. The two or more low-index sublayers may have a same refractive index or different refractive indices to form a refractive index gradient.

For example, DBR pair #1 may be p-doped (or n-doped) while DBR pair #2 is n-doped (or p-doped), respectively. DBR pair #N may be oppositely doped with respect to an adjacent DBR pair, and N may be an integer greater than two. In other words, both the high-index layer 401 and the low-index layer 402 of DBR pair #1 may be p-type (or n-type) doped, and both the high-index layer 401 and the low-index layer 402 of DBR pair #2 may be n-type (or p-type) doped, respectively. Thus, adjacent DBR pairs may have opposite doping. Thus, current-blocking junctions may be formed by alternating p-doped and n-doped structures within the current-blocking DBR 400.

In addition, the current-blocking DBR 400 may include one or more gradient layers between high-index and low-index layers, which are not shown in FIG. 4. The gradient layers may be either n-doped, p-doped, undoped, or n-doped in one part and p-doped in a remaining part.

The current-blocking DBR 400 can provide superb performance for current-blocking due to a number of identical or similar p-n junctions which may also be a heterojunction. The heterojunction is formed by dissimilar semiconductor materials which have different energy bands. For example, a GaAs-based AlGaAs DBR may have a higher aluminum composition in the low-index layers and a lower aluminum composition in the high-index layers, such that two adjacent layers form a heterojunction.

FIG. 4 is provided as an example. Other examples may differ from what is described with regard to FIG. 4.

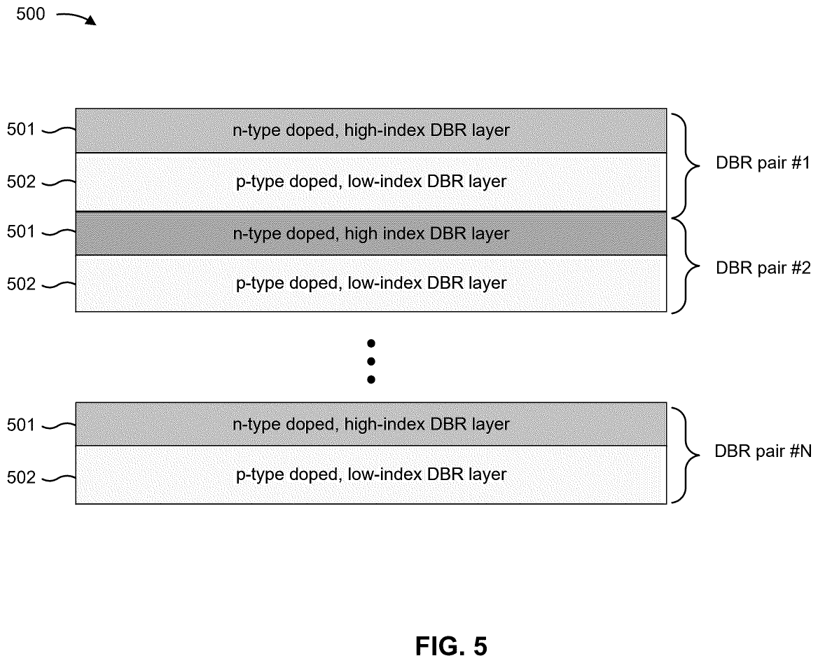

FIG. 5 shows a current-blocking DBR 500 according to one or more implementations. The current-blocking DBR 500 may be implemented as the current-blocking DBR 204 of emitter 200. The current-blocking DBR 500 includes alternating n-type high-index layers 501 and p-type low-index layers 502.

In addition, the current-blocking DBR 500 may include one or more gradient layers (not illustrated) between neighboring pairs of high-index and low-index layers. For example, one or more gradient layers may be provided between each neighboring pair of high-index and low-index layers of the current-blocking DBR 500. The one or more gradient layers may be either n-doped or p-doped, or n-doped in one part and p-doped in a remaining part.

A neighboring pair of high-index and low-index layers (i.e., a DBR pair) may include two oppositely doped layers, where a full section of the high-index layer 501 is n-type doped, while a full section of the low-index layer 502 is p-type doped. There may be other different configurations or schemes. For example, part of the high-index layer 501 and/or an adjacent part of the low-index layer 502 may be n-doped, and a remaining part of the high-index layer 501 and/or an adjacent part of the low-index layer 502 may be p-doped. Thus, each high-index layer 501 may be formed by two or more high-index sublayers, which may have a same doping type or opposite doping types. The two or more high-index sublayers may have a same refractive index or different refractive indices to form a refractive index gradient. Additionally, each low-index layer 502 may be formed by two or more low-index sublayers, which may have a same type doping or opposite dopings. The two or more low-index sublayers may have a same refractive index or different refractive indices to form a refractive index gradient

For example, DBR pair #1 may be p-doped (or n-doped) while DBR pair #2 is n-doped (or p-doped), respectively. DBR pair #N may be oppositely doped with respect to an adjacent DBR pair. In other words, both the high-index layer 501 and the low-index layer 502 of DBR pair #1 is p-type (or n-type) doped, and both the high-index layer 501 and the low-index layer 502 of DBR pair #2 is n-type (or p-type) doped, respectively. Thus, adjacent DBR pairs may have opposite doping. Thus, current-blocking junctions may be formed by alternating p-doped and n-doped structures within the current-blocking DBR 500.

In addition, the current-blocking DBR 500 may include one or more gradient layers between high-index and low-index layers, which are not shown in FIG. 5. The gradient layers may be either n-doped, p-doped, undoped, or n-doped in one part and p-doped in a remaining part.

The current-blocking DBR 500 can provide superb performance for current-blocking due to a number of identical or similar p-n junctions which may also be a heterojunction. The heterojunction is formed by dissimilar semiconductor materials which have different energy bands. For example, a GaAs-based AlGaAs DBR may have a higher aluminum composition in the low-index layers and a lower aluminum composition in the high-index layers such that two adjacent layers form a heterojunction.

FIG. 5 is provided as an example. Other examples may differ from what is described with regard to FIG. 5.

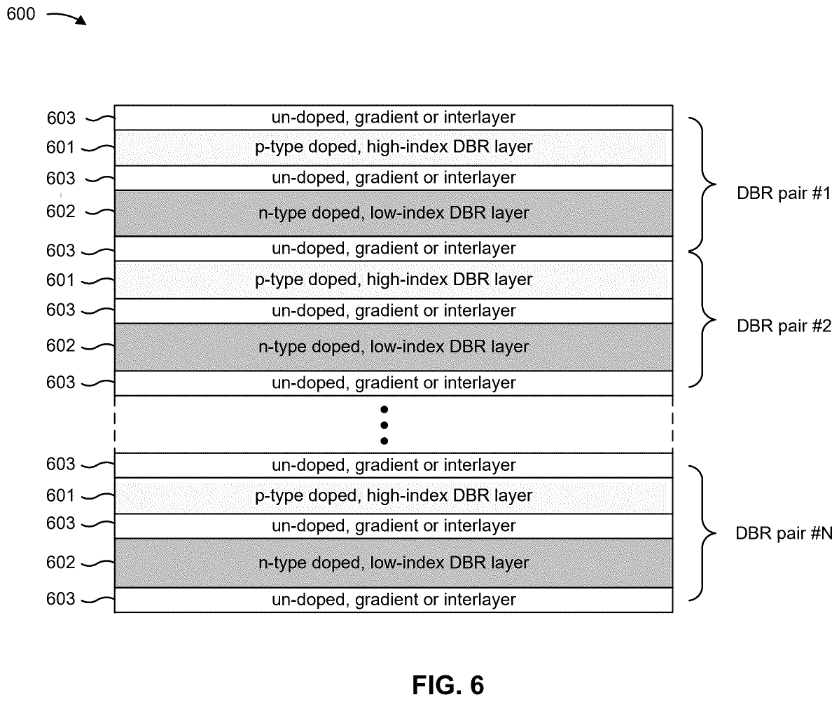

FIG. 6 shows a current-blocking DBR 600 according to one or more implementations. The current-blocking DBR 600 may be implemented as the current-blocking DBR 204 of emitter 200. The current-blocking DBR 600 includes alternating p-type high-index layers 601 and n-type low-index layers 602. In addition, the current-blocking DBR 600 includes an undoped layer 603 (e.g., an interlayer or an intrinsic layer) between each pair of high-index and low-index layers. Thus, each DBR pair includes at least one undoped layer 603. Each DBR pair may include three differently doped layers (e.g., a p-doped layer, an n-doped layer, and an undoped (intrinsic) layer arranged between the p-doped layer and n-doped layer).

There may be other different configurations or schemes. For an example, part of the high-index layer 601, an adjacent part of the undoped layer 603, and/or the low-index layer 602 may be p-doped (or n-doped). Additionally, part of the undoped layer 603 or part of the high-index layer 601 (or low-index layer 602) may be undoped. Additionally, a remaining part of the high-index layer 601, the adjacent part of the undoped layer 603, and/or the low-index layer 602 may be n-doped (or p-doped), respectively. For an example, DBR pair #1 or part of DBR pair #1 may be p-doped (or n-doped), DBR pair #2 or part of DBR pair #2 may be undoped, and DBR pair #3 or part of DBR pair #3 may be n-doped (or p-doped), respectively. Thus, adjacent DBR pairs may form a p-n junction. In some implementations, each DBR pair may include one or more p-n junctions.

In some implementations, the undoped layers 603 may be gradient layers, which have an intermediate refractive index value between a high refractive index value of the high-index layer 601 and a low refractive index value of the low-index layer 602. For example, the undoped layer 603 of DBR pair #1 may have an intermediate refractive index value between a high refractive index value of the high-index layer 601 of DBR pair #1 and a low refractive index value of the low-index layer 602 of DBR pair #1. Thus, the undoped layer 603 of DBR pair #1 may provide a gradual semiconductor band-gap change or a stepped semiconductor band-gap change between high-index and low-index materials of DBR pair #1. The undoped layer 603 of DBR pair #2 may have an intermediate refractive index value between a high refractive index value of the high-index layer 601 of DBR pair #2 and a low refractive index value of the low-index layer 602 of DBR pair #2. Thus, the undoped layer 603 of DBR pair #2 may provide a gradual semiconductor band-gap change or a stepped semiconductor band-gap change between high-index and low-index materials of DBR pair #2. In some implementations, two or more the undoped layers 603 may be provided between the high-index and low-index layers of a DBR pair. The two or more the undoped layers 603 may be gradient layers, each having a different intermediate refractive index value between a high refractive index value of the high-index layer 601 and a low refractive index value of the low-index layer 602 in order to provide a gradual or stepped transition between the high refractive index value of the high-index layer 601 and the low refractive index value of the low-index layer 602.

In some implementations, one or more undoped layers 603 may be provided between adjacent DBR pairs. In some implementations, the one or more undoped layers 603 provided between adjacent DBR pairs may be gradient layers each having a different intermediate refractive index value between a high refractive index value of a neighboring high-index layer 601 and a low refractive index value of a neighboring low-index layer 602 in order to provide a gradual or stepped transition between the high refractive index value of the high-index layer 601 and the low refractive index value of the low-index layer 602.

The current-blocking DBR 600 can deliver superb performance for current-blocking due to a number of identical or similar p-i-n junctions which may also be hetero-junctions.

FIG. 6 is provided as an example. Other examples may differ from what is described with regard to FIG. 6.

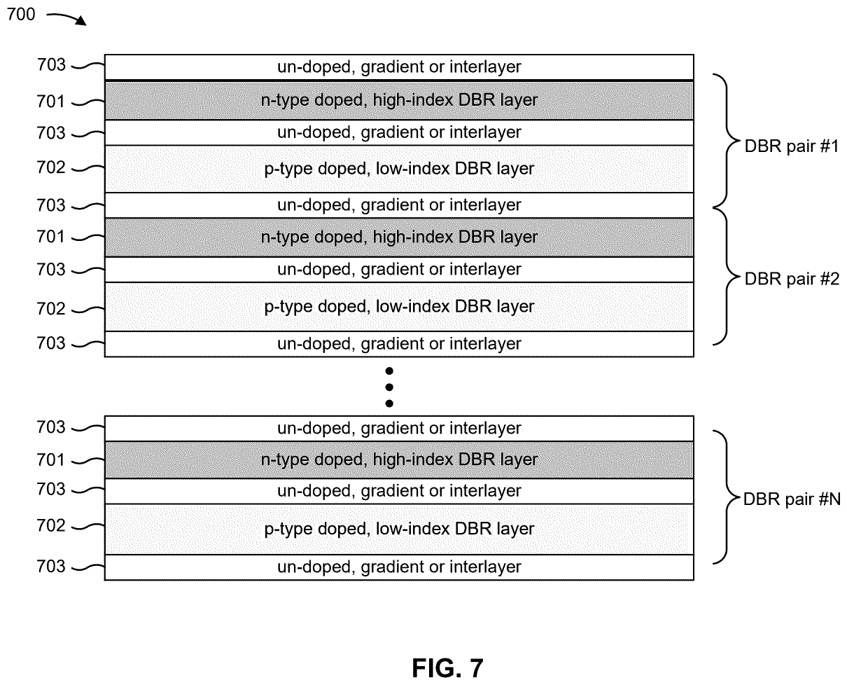

FIG. 7 shows a current-blocking DBR 700 according to one or more implementations. The current-blocking DBR 700 may be implemented as the current-blocking DBR 204 of emitter 200. The current-blocking DBR 700 includes alternating p-type high-index layers 701 and n-type low-index layers 702. In addition, the current-blocking DBR 700 includes an undoped layer 703 (e.g., an interlayer or an intrinsic layer) between each pair of high-index and low-index layers. Thus, each DBR pair includes at least one undoped layer 703. Each DBR pair may include three differently doped layers (e.g., a p-doped layer, an n-doped layer, and an undoped (intrinsic) layer arranged between the p-doped layer and n-doped layer). The current-blocking DBR 700 is similar to the current-blocking DBR 600, with the exception that the high-index layers 701 are n-type doped and the low-index layers 702 are p-typed doped. Additionally, the undoped layers 703 may be graduated layers with intermediate refractive index values that may provide a gradual semiconductor band-gap change or a stepped semiconductor band-gap change between high-index and low-index materials of the alternately stacked high-index layers and low-index layers.

There may be other different configurations or schemes. For an example, part of the high-index layer, an adjacent part of the gradient layer, and/or the low-index layer may be p-doped (or n-doped). Additionally, part of the gradient layer or part of the high (or low-index) layer may be undoped. Additionally, a remaining part of the high-index layer, the adjacent part of the gradient layer, and/or the low-index layer may be n-doped (or p-doped), respectively. For an example, DBR pair #1 or part of DBR pair #1 may be p-doped (or n-doped), DBR pair #2 or part of DBR pair #2 may be undoped, and DBR pair #3 or part of DBR pair #3 may be n-doped (or p-doped), respectively.

FIG. 7 is provided as an example. Other examples may differ from what is described with regard to FIG. 7.

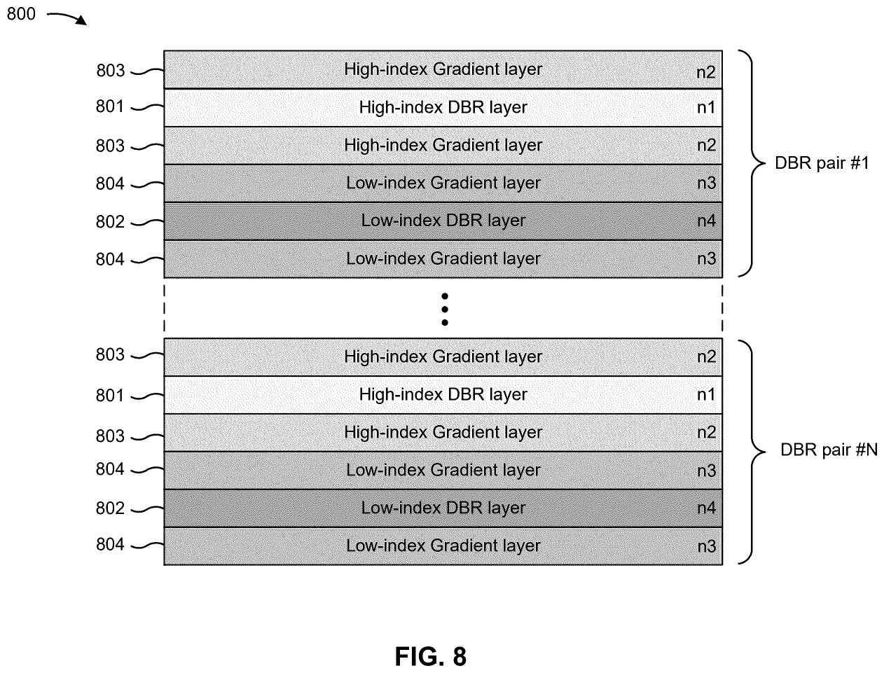

FIG. 8 shows a current-blocking DBR 800 according to one or more implementations. The current-blocking DBR 800 may be implemented as the current-blocking DBR 204 of emitter 200. The current-blocking DBR 800 includes alternating high-index layers 801 and low-index layers 802. The high-index layers 801 may have a high refractive index value n1 (e.g., a maximum or local maximum refractive index value) and the low-index layers 802 may have a low refractive index value n4 (e.g., a minimum or local minimum refractive index value), with n1>n4. The high-index layers 801 may be p-doped and the low-index layers 802 may be n-doped, or the high-index layers 801 may be n-doped and the low-index layers 802 may be p-doped. A neighboring pair of high-index and low-index layers may form a DBR pair (e.g., DBR pair #1, . . . , and DBR pair #N) that includes two oppositely doped. layers. In some implementations, an intrinsic layer may be arranged between adjacent DBR pairs.

In addition, each DBR pair (e.g., DBR pair #1, . . . , and DBR pair #N) may include two or more gradient layers (e.g., a plurality of gradient layers), including a first gradient layer 803 (e.g., a high-index gradient layer) and a second gradient layer 804 (e.g., a low-index gradient layer). One of the first gradient layers 803 may be arranged between a high-index layer 801 and a second gradient layer 804 of a respective DBR pair. One of the second gradient layers 804 may be arranged between a low-index layer 802 and a first gradient layer 803 of a respective DBR pair. In some implementations, the high-index layer 801 may be arranged between two first gradient layers 803, and the low-index layer 802 may be arranged between two second gradient layers 804.

The first gradient layers 803 may have an intermedia refractive index value n2 (e.g., a first intermedia refractive index value) that is less than the high refractive index value n1. The second gradient layers 804 may have an intermedia refractive index value n3 (e.g., a second intermedia refractive index value) that is greater than the low refractive index value n4 and less than the intermedia refractive index value n3. Thus, the refractive index values of a DBR pair may transition between the high refractive index value n1 and the low refractive index value n4 according to the following condition: n1>n2>n3>n4. The refractive index values n2 and n3 may be referred to as intermediate refractive index values. The gradient layers may provide a gradual or stepped transition between the high refractive index value n1 of the high-index layer 801 and the low refractive index value n4 of the low-index layer 802. Thus, the gradient layers of the current-blocking DBR 800 may provide a gradual semiconductor band-gap change or a stepped semiconductor band-gap change between high-index and low-index materials of the alternately stacked high-index layers 801 and low-index layers 802.

In some implementations, the first gradient layers 803 and the second gradient layers 804 may be intrinsic layers. Alternatively, in some implementations, the first gradient layers 803 and the second gradient layers 804 may be doped layers. For example, the first gradient layers 803 may have a same doping type as the high-index layers 801, and the second gradient layers 804 may have a same doping type as the low-index layers 802. In some implementations, the second gradient layers 804 and the low-index layers 802 may be oppositely doped, and the first gradient layers 803 and the high-index layers 801 may be oppositely doped.

In some implementations, the low-index layer 802 and the second gradient layer 804 of a DBR pair are sublayers of a low-index layer. Thus, a low-index layer may be formed by the low-index layer 802 and the second gradient layer 804. In other words, the low-index layer 802 may itself be a gradient layer. Accordingly, each low-index layer may include a first plurality of gradient sublayers (e.g., layers 802 and 804) that provide a first transition in refractive index across a range of low refractive indices (e.g., across a range of n3 to n4). The first plurality of gradient sublayers that make up the low-index layer may include three or more gradient layers of different refractive indices. The first plurality of gradient sublayers may have a same doping type. Thus, the second gradient layers 804 may have a same doping type as the low-index layers 802.

In some implementations, the high-index layer 801 and the first gradient layer 803 of a DBR pair are sublayers of a high-index layer. Thus, a high-index layer may be formed by the high-index layer 801 and the first gradient layer 803. In other words, the high-index layer 801 may itself be a gradient layer. Accordingly, each high-index layer may include a second plurality of gradient sublayers (e.g., layers 801 and 803) that provide a second transition in refractive index across a range of high refractive indices (e.g., across a range of n1 to n2). The second plurality of gradient sublayers that make up the high-index layer may include three or more gradient layers of different refractive indices. The second plurality of gradient sublayers may have a same doping type. Thus, the first gradient layers 803 may have a same doping type as the high-index layers 801.

In some implementations, the first plurality of gradient sublayers may have alternating doping types, and the second plurality of gradient sublayers may have alternating doping types. For example, the second gradient layers 804 and the low-index layers 802 may be oppositely doped, and the first gradient layers 803 and the high-index layers 801 may be oppositely doped.

FIG. 8 is provided as an example. Other examples may differ from what is described with regard to FIG. 8.

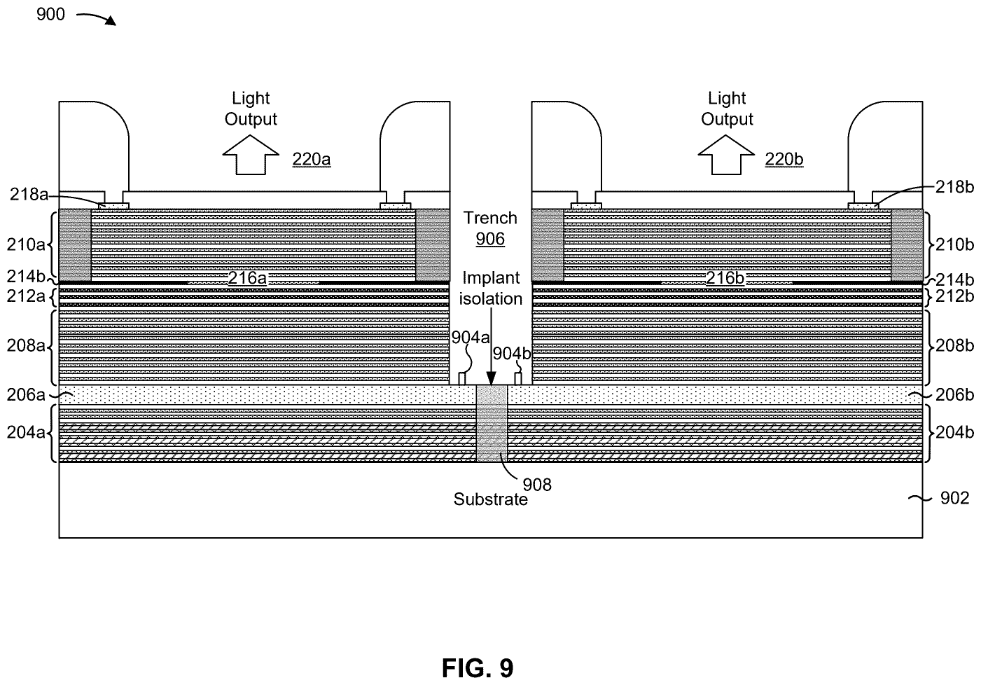

FIG. 9 shows an addressable emitter array 900 according to one or more implementations. The addressable emitter array 900 may include a plurality of addressable emitters (e.g., addressable VCSEL devices). Thus, the addressable emitter array 900 may be an addressable VCSEL or vertical emitter array. For example, the addressable emitter array 900 may include a plurality of emitters (e.g., a plurality of emitters 200) arranged on a common substrate 902 (e.g., substrate 202). Two laterally adjacent emitters of the addressable emitter array 900 are shown in FIG. 9.

The addressable emitter array 900 may include the common substrate 902, a first emitter 200a arranged on the common substrate 902, and a second emitter 200b arranged on the common substrate 902. The first emitter 200a and the second emitter 200b may be selectively addressable. In some implementations, the first emitter 200a and the second emitter 200b may be independently enabled and disabled. The first emitter 200a and the second emitter 200b each have a similar structure as the emitter 200 described in connection with FIGS. 2-8. Thus, the first emitter 200a may include a first current-blocking DBR 204a arranged on the common substrate 902; a first bottom contact layer 206a arranged on the first current-blocking DBR 204a and associated with a first current; a first bottom DBR 208a arranged on the first bottom contact layer 206a; a first top DBR 210a arranged on the first bottom DBR 208a; a first active region 212a configured to generate a first laser light, wherein the first active region 212a is arranged between the first bottom DBR 208a and the first top DBR 210a; a first oxidation layer 214a that defines a current confinement aperture 216a, a first top contact layer 218a arranged on the first top DBR 210a and associated with a first current; and a first optical output 220a arranged over the first top DBR 210a, wherein the first emitter 200a is configured to emit the first laser light via the first optical output 220a. In addition, the first emitter 200a may include a contact pad 904a that is in electrical contact with the first bottom contact layer 206a. The first current-blocking DBR 204a includes a first plurality of p-n junctions connected vertically in series to form a first bidirectional current-blocking structure. Moreover, the first current-blocking DBR 204a is a first optical reflector configured to reflect a portion of the first laser light generated by the first active region 212a toward the first optical output 220a.

The second emitter 200b may include a second current-blocking DBR 204b arranged on the common substrate 902; a second bottom contact layer 206b arranged on the second current-blocking DBR 204b and associated with a second current; a second bottom DBR 208b arranged on the second bottom contact layer 206b; a second top DBR 210b arranged on the second bottom DBR 208b; a second active region 212b configured to generate a second laser light, wherein the second active region 212b is arranged between the second bottom DBR 208b and the second top DBR 210b; a second oxidation layer 214b that defines a current confinement aperture 216b, a second top contact layer 218b arranged on the second top DBR 210b and associated with a second current; and a second optical output 220b arranged over the second top DBR 210b, wherein the second emitter 200b is configured to emit the second laser light via the second optical output 220b. In addition, the second emitter 200b may include a contact pad 904b that is in electrical contact with the second bottom contact layer 206b. The second current-blocking DBR 204b includes a second plurality of p-n junctions connected vertically in series to form a second bidirectional current-blocking structure. Moreover, the second current-blocking DBR 204b is a second optical reflector configured to reflect a portion of the second laser light generated by the second active region 212b toward the second optical output 220b.

The first emitter 200a and the second emitter 200b may be at least partially separated by a vertical trench 906. The vertical trench 906 may extend vertically from an uppermost layer of the first emitter 200a and the second emitter 200b down to at least the first bottom contact layer 206a and the second bottom contact layer 206b. Thus, the vertical trench 906 may provide lateral separation and electrical isolation between the first emitter 200a and the second emitter 200b.

In addition, the addressable emitter array 900 may include a vertical isolation region between each laterally adjacent emitter. The vertical isolation region may extend vertically through a bottom contact buffer layer and the current-blocking DBR to the common substrate 902. For example, the addressable emitter array 900 may include an isolation region 908 configured to electrically isolate the first emitter 200a and the second emitter 200b. The isolation region 908 may be arranged laterally between the first bottom contact layer 206a and the second bottom contact layer 206b, and laterally between the first current-blocking DBR 204a and the second current-blocking DBR 204b.

The first bottom contact layer 206a and the second bottom contact layer 206b may be formed from a contact buffer layer. In other words, the first bottom contact layer 206a and the second bottom contact layer 206b may be formed from a common contact layer. In addition, the first current-blocking DBR 204a and the second current-blocking DBR 204b may be formed from a common current-blocking DBR. The isolation region 908 may be an implant isolation region formed by implantation that extends vertically through the contact buffer layer and the common current-blocking DBR to the common substrate 902 or partially into the common substrate 902 in order to electrically isolate the first bottom contact layer 206a and the second bottom contact layer 206b. Thus, the isolation region 908 may prevent current leakage between the first emitter 200a and the second emitter 200b. In addition, the first current-blocking DBR 204a may electrically isolate the common substrate 902 from the first bottom contact layer 206a, and the second current-blocking DBR 204b may electrically isolate the common substrate 902 from the second bottom contact layer 206b. Thus, the first current-blocking DBR 204a, the second current-blocking DBR 204b, and the isolation region 908 may provide electrical isolation between the first emitter 200a and the second emitter 200b.

The addressable emitter array 900 may be an array of stripes of emitters or a matrix-addressable array. The matrix-addressable array may be configured for two-dimensional (grid type) addressing. Alternatively, a more complicated addressing of current or voltage may be used, including subarray addressing or addressing a specific pattern/distribution of emitters.

For top emitting matrix-addressable VCSEL arrays, it may be necessary to add vertical isolation in the current-blocking DBR in order to separate the bottom contact layers between different emitters or sub-arrays in addition to separating the top contact layers. For example, to electrically isolate two emitters or two sub-arrays, the addressable emitter array 900 may include the implant isolation region to electrically isolate the bottom contact layers of the laterally adjacent emitters. A depth of the implant isolation region may extend down through part of the common current-blocking DBR, or deeper down onto or into the common substrate 902. In order to make electrical contact with the bottom contact layers, a trench or moat may be etched to expose the bottom contact buffer layer.

In some implementations, there may be additional passivation/isolation layers such as SiOx, SiNx, atomic layer deposition (ALD) layer, polymer, polyamide, and/or another type of dielectric or ceramic material on the cathode and the anode, and/or between cathode and anode.

In addition, one or more aspects may be included in the above-described implementations, including (1) multi-junction VCSELs described in the context herein can have one, two, three, or more junctions; (2) an electric polarity of the VCSEL from the top to bottom can be either a p-i-n or n-i-p structure. A top semiconductor contact or cap can be either a p-type semiconductor or an n-type semiconductor. Also, all or part of a p-DBR can be replaced by an n-DBR by using a tunnel junction, or vice versa; (3) oxide-confined VCSELs may have one, two, or more oxide layers at either a p-side or an n-side; (4) the use of an optical aperture layer in VCSELs as current and mode confinement is optional and can be replaced with different approaches such as implantation passivation, mesa or moat trench isolation, or a buried tunnel junction; (5) the substrate may be a GaAs, InP, InGaAs, GaSb, Si, Ge, GaP, GaN, ZnO, or a sapphire substrate, which is utilized to grow an epitaxial structure on top. The substrate may be an n-type, a p-type, a semi-insulating type, an insulating type, or a conductive type. Even if epitaxy is used on a semi-insulating or an insulating substrate, the above-described implementations may improve electrical isolation, for example, in a case where the vertical isolation region does not extend entirely down to the substrate.

In some implementations, a buffer layer may be arranged on the substrate 902, vertically between the substrate 902 and the common current-blocking DBR. For example, a thin buffer layer of GaAs may be grown on the substrate 902 (e.g., a GaAs substrate) to provide a clean surface to begin growing the DBR layers of the common current-blocking DBR. The thin buffer layer could be undoped or low doped to provide high electrical resistance. The isolation region 908 may extend at least to the buffer layer. For example, the isolation region 908 may extend to the buffer layer, partially through the buffer layer, or completely through the buffer layer to the substrate 902. The substrate 902 may be a high electrical resistance substrate that provides electrical isolation between emitters of the addressable emitter array 900.

FIG. 9 is provided as an example. Other examples may differ from what is described with regard to FIG. 9.

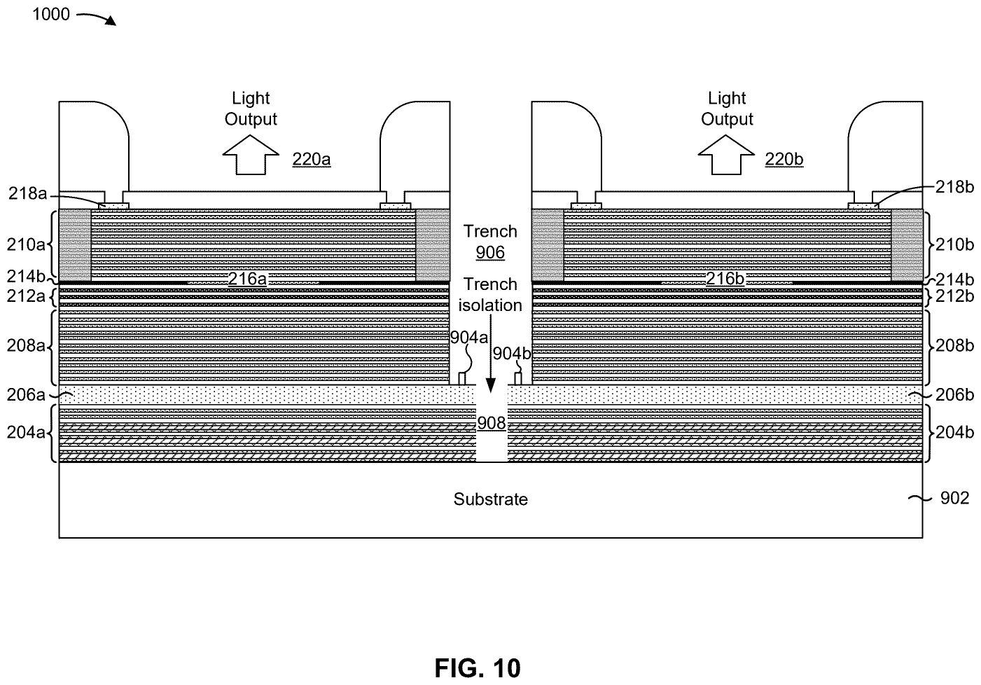

FIG. 10 shows an addressable emitter array 1000 according to one or more implementations. The addressable emitter array 1000 is similar to the addressable emitter array 900, with the exception that the isolation region 908 is an isolation trench, which may be an extension of the vertical trench 906. The isolation trench may extend vertically through the contact buffer layer and the common current-blocking DBR to separate the first bottom contact layer 206a and the second bottom contact layer 206b, and to separate the first current-blocking DBR 204a and the second current-blocking DBR 204b. The isolation trench may extend vertically to the common substrate 902 or partially into the common substrate 902 in order to electrically isolate the first bottom contact layer 206a and the second bottom contact layer 206b.

Thus, the isolation region 908 may prevent current leakage between the first emitter 200a and the second emitter 200b. In addition, the first current-blocking DBR 204a may electrically isolate the common substrate 902 from the first bottom contact layer 206a, and the second current-blocking DBR 204b may electrically isolate the common substrate 902 from the second bottom contact layer 206b. Thus, the first current-blocking DBR 204a, the second current-blocking DBR 204b, and the isolation region 908 may provide electrical isolation between the first emitter 200a and the second emitter 200b.

In some implementations, a buffer layer may be arranged on the substrate 902, vertically between the substrate 902 and the common current-blocking DBR. For example, a thin buffer layer of GaAs may be grown on a GaAs substrate to provide a clean surface to begin growing the DBR layers of the common current-blocking DBR. The thin buffer layer could be undoped or low doped to provide high electrical resistance. The isolation region 908 may extend at least to the buffer layer. For example, the isolation region 908 may extend to the buffer layer, partially through the buffer layer, or completely through the buffer layer to the substrate 902. The substrate 902 may be a high electrical resistance substrate that provides electrical isolation between emitters of the addressable emitter array 1000.

FIG. 10 is provided as an example. Other examples may differ from what is described with regard to FIG. 10.

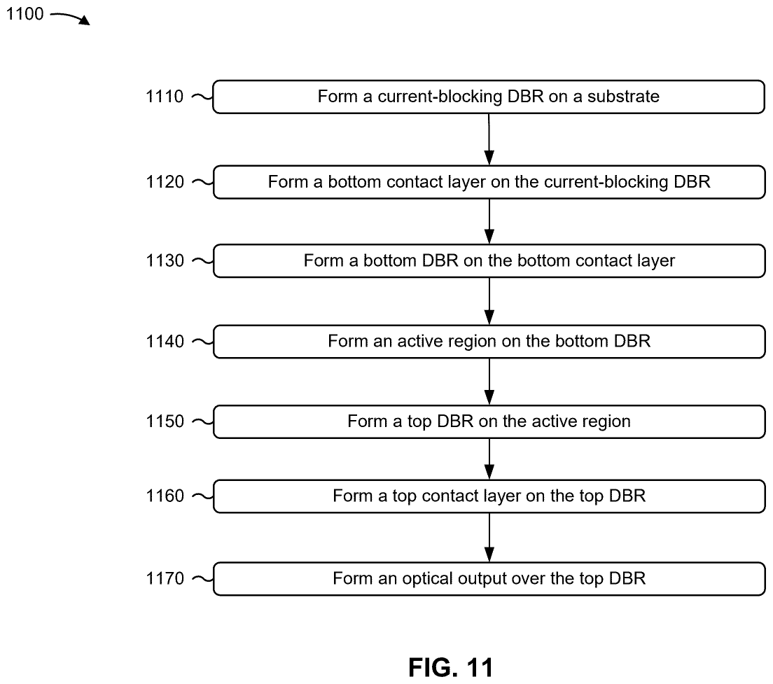

FIG. 11 is a flowchart of an example process 1100 associated with a vertical cavity surface emitting laser device. In some implementations, one or more process blocks of FIG. 11 are performed by method/process (including epitaxy and wafer fabrication) to form electrically isolated VCSELs or vertical emitter arrays with a current-blocking DBR and with a vertical isolation region (e.g., implant isolation or trench isolation). In some implementations, one or more process blocks of FIG. 11 are performed by device, a group of devices, or fabrication system or systems.

As shown in FIG. 11, process 1100 may include forming a current-blocking DBR on a substrate (block 1110). The current-blocking DBR may include a plurality of p-n junctions connected vertically in series to form a bidirectional current-blocking structure, as described above.

As further shown in FIG. 11, process 1100 may include forming a bottom contact layer on the current-blocking DBR (block 1120). The current-blocking DBR may electrically isolate the substrate from the bottom contact layer, as described above.

As further shown in FIG. 11, process 1100 may include forming a bottom DBR on the bottom contact layer (block 1130).

As further shown in FIG. 11, process 1100 may include forming an active region on the bottom DBR (block 1140). The active region may be configured to generate a laser light, as described above.

As further shown in FIG. 11, process 1100 may include forming a top DBR on the active region (block 1150).

As further shown in FIG. 11, process 1100 may include forming a top contact layer on the top DBR (block 1160).

As further shown in FIG. 11, process 1100 may include forming an optical output over the top DBR (block 1170). The optical output may be configured to emit the laser light from the emitter, as described above.

When forming an addressable emitter array, such as the addressable emitter array 900 or the addressable emitter array 1000, the process 1100 may be performed for each emitter. In addition, the process 1100 may include forming a vertical trench (e.g., vertical trench 906) between adjacent emitters, as described above. In addition, the process 1100 may include forming an isolation region (e.g., isolation region 908) between adjacent emitters, as described above.

Process 1100 may include additional implementations, such as any single implementation or any combination of implementations described below and/or in connection with one or more other processes described elsewhere herein.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An emitter, comprising:
a substrate;
a current-blocking distributed Bragg reflector (DBR) arranged on the substrate, wherein the current-blocking DBR includes a plurality of p-n junctions connected vertically in series to form a bidirectional current-blocking structure;
a bottom contact layer arranged on the current-blocking DBR;
a bottom DBR arranged on the bottom contact layer;
a top DBR arranged on the bottom DBR;
an active region configured to generate a laser light, wherein the active region is arranged between the bottom DBR and the top DBR;
a top contact layer arranged on the top DBR; and
an optical output arranged over the top DBR, wherein the emitter is configured to emit the laser light via the optical output.

2. The emitter of claim 1, wherein the current-blocking DBR is configured to electrically isolate the substrate from the bottom contact layer.

3. The emitter of claim 1, wherein the current-blocking DBR is an optical reflector configured to reflect a portion of the laser light generated by the active region toward the optical output.

4. The emitter of claim 1, wherein the plurality of p-n junctions include a plurality of p-i-n junctions.

5. The emitter of claim 1, wherein the current-blocking DBR comprises a plurality of alternately stacked high-index layers and low-index layers,
wherein the high-index layers are p-doped and the low-index layers are n-doped, or the high-index layers are n-doped and the low-index layers are p-doped.

6. The emitter of claim 5, wherein the current-blocking DBR comprises a plurality of gradient layers,
wherein each gradient layer of the plurality of gradient layers is arranged between a respective pair of high-index and low-index layers of the current-blocking DBR, and
wherein each gradient layer of the plurality of gradient layers has a respective intermediate refractive index value between a high refractive index value and a low refractive index value of the respective pair of high-index and low-index layers.

7. The emitter of claim 5, wherein the current-blocking DBR comprises a plurality of gradient layers that provide a gradual semiconductor band-gap change or a stepped semiconductor band-gap change between high-index and low-index materials of the alternately stacked high-index layers and low-index layers.

8. The emitter of claim 5, wherein a first part of each high-index layer is p-doped and a second part of each high-index layer is n-doped such that the plurality of p-n junctions are formed with the low-index layers.

9. The emitter of claim 5, wherein a first part of each low-index layer is p-doped and a second part of each low-index layer is n-doped such that the plurality of p-n junctions are formed with the high-index layers.

10. The emitter of claim 5, wherein the current-blocking DBR comprises a plurality of intrinsic layers,
wherein each intrinsic layer of the plurality of intrinsic layers is arranged between a respective pair of p-doped and n-doped layers of the current-blocking DBR.

11. The emitter of claim 10, wherein each intrinsic layer of the plurality of intrinsic layers is part of a respective high-index layer of the current-blocking DBR, or is part of a respective low-index layer of the current-blocking DBR.

12. The emitter of claim 1, wherein the current-blocking DBR comprises a plurality of alternately stacked high-index layers and low-index layers,
wherein each low-index layer comprises a first plurality of gradient sublayers that provide a first transition in refractive index across a range of low refractive indices, and
wherein each high-index layer comprises a second plurality of gradient sublayers that provide a second transition in refractive index across a range of high refractive indices.

13. The emitter of claim 12, wherein the high-index layers are p-doped and the low-index layers are n-doped, or the high-index layers are n-doped and the low-index layers are p-doped.

14. The emitter of claim 1, wherein the current-blocking DBR comprises a plurality of alternately stacked high-index layers and low-index layers,
wherein the plurality of alternately stacked high-index layers and low-index layers form a plurality of DBR pairs,
wherein each DBR pair includes a respective neighboring pair of high-index and low-index layers, and
wherein the plurality of DBR pairs are alternately p-doped and n-doped to form the plurality of p-n junctions.

15. The emitter of claim 14, wherein each DBR pair includes an intrinsic layer arranged between the respective neighboring pair of high-index and low-index layers.

16. An emitter array, comprising:
a substrate;
a first emitter arranged on the substrate, wherein the first emitter comprises:
a first current-blocking distributed Bragg reflector (DBR) arranged on the substrate, wherein the first current-blocking DBR includes a first plurality of p-n junctions connected vertically in series to form a first bidirectional current-blocking structure;
a first bottom contact layer arranged on the first current-blocking DBR and associated with a first current;
a first bottom DBR arranged on the first bottom contact layer;
a first top DBR arranged on the first bottom DBR;
a first active region configured to generate a first laser light, wherein the first active region is arranged between the first bottom DBR and the first top DBR;
a first top contact layer arranged on the first top DBR and associated with a first current; and
a first optical output arranged over the first top DBR, wherein the first emitter is configured to emit the first laser light via the first optical output;
a second emitter arranged on the substrate, wherein the second emitter is adjacent to the first emitter, and wherein the second emitter comprises:
a second current-blocking DBR arranged on the substrate, wherein the second current-blocking DBR includes a second plurality of p-n junctions connected vertically in series to form a second bidirectional current-blocking structure;
a second bottom contact layer arranged on the second current-blocking DBR and associated with a second current;
a second bottom DBR arranged on the second bottom contact layer;
a second top DBR arranged on the second bottom DBR;
a second active region configured to generate a second laser light, wherein the second active region is arranged between the second bottom DBR and the second top DBR;
a second top contact layer arranged on the second top DBR and associated with the second current; and
a second optical output arranged over the second top DBR, wherein the second emitter is configured to emit the second laser light via the second optical output; and
an isolation region configured to electrically isolate the first emitter and the second emitter, wherein the isolation region is arranged laterally between the first bottom contact layer and the second bottom contact layer, and laterally between the first current-blocking DBR and the second current-blocking DBR.

17. The emitter array of claim 16, wherein the first bottom contact layer and the second bottom contact layer are formed from a contact buffer layer, and
the isolation region is an isolation trench that extends vertically through the contact buffer layer to separate the first bottom contact layer and the second bottom contact layer, and
wherein the isolation trench extends vertically to the substrate or partially into the substrate in order to electrically isolate the first bottom contact layer and the second bottom contact layer.

18. The emitter array of claim 16, wherein the first bottom contact layer and the second bottom contact layer are formed from a contact buffer layer,
wherein the first current-blocking DBR and the second current-blocking DBR are formed from a common current-blocking DBR, and
wherein the isolation region is an implant isolation region that extends vertically through the contact buffer layer and the common current-blocking DBR to the substrate or partially into the substrate in order to electrically isolate the first bottom contact layer and the second bottom contact layer.

19. The emitter array of claim 16, wherein the isolation region is configured to electrically isolate the first bottom contact layer and the second bottom contact layer.

20. The emitter array of claim 16, wherein the first current-blocking DBR is configured to electrically isolate the substrate from the first bottom contact layer, and
wherein the second current-blocking DBR is configured to electrically isolate the substrate from the second bottom contact layer.

21. The emitter array of claim 16, wherein the first current-blocking DBR is a first optical reflector configured to reflect a portion of the first laser light generated by the first active region toward the first optical output, and
wherein the second current-blocking DBR is a second optical reflector configured to reflect a portion of the second laser light generated by the second active region toward the second optical output.

22. The emitter array of claim 16, wherein the first emitter and the second emitter are selectively addressable.

23. A method of manufacturing an emitter, the method comprising:
forming a current-blocking distributed Bragg reflector (DBR) on a substrate, wherein the current-blocking DBR includes a plurality of p-n junctions connected vertically in series to form a bidirectional current-blocking structure;
forming a bottom contact layer on the current-blocking DBR, wherein the current-blocking DBR is configured to electrically isolate the substrate from the bottom contact layer;
forming a bottom DBR on the bottom contact layer;
forming an active region on the bottom DBR, wherein the active region is configured to generate a laser light;
forming a top DBR on the active region;
forming a top contact layer on the top DBR; and
forming an optical output over the top DBR, wherein the optical output is configured to emit the laser light from the emitter.
